(19) United States
(12) Patent Application Publication
(10) Pub. No.: US 2005/0133804 A1
(43) Pub. Date: Jun. 23, 2005

(54) Display device with a lenticular lens and the method of making the same

(75) Inventors: Chun-Che Hsu, Tainan Science-Based Industrial Park (TW); Hong-Ru Gou, Tainan Science-Based Industrial Park (TW); Chia-Tin Chung, Tainan Science-Based Industrial Park (TW)

Correspondence Address: Ladas & Parry, 26 West 61 Street, New York, NY, 10023, US

(73) Assignees: CHI MEI OPTOELECTRONICS CORP.; KYOCERA CORPORATION

(21) Appl. No.: 10/998,772

(22) Filed: Nov. 29, 2004

(30) Foreign Application Priority Data
Dec. 2, 2003 (TW) 092133858

(51) Int. Cl. H01L 33/00

(52) U.S. Cl. 257/98

(57) ABSTRACT

The present invention relates to a display device comprising a substrate, a display module, a lenticular lens and a glass cap. The display module is attached to the substrate and is used for emitting light. The lenticular lens is disposed above the display module and is used for changing the luminous intensity distribution of the light emitted by the display module. The glass cap is disposed above the lenticular lens and is sealed with the substrate for capping the lenticular lens and the display module. According to the display device of the invention, the disunity of the luminous intensity distribution of the light emitted by the display module in different view angles is improved, which facilitates the color control. The present invention also relates to a method of making a display device with a lenticular lens.

### BACKGROUND OF THE INVENTION

1. Field of the Invention

The present invention relates to a display device, especially to a display device having a lenticular lens therein.

2. Description of the Related Art

Referring to FIG. 1, a cross-sectional view of a conventional organic light emitting diode is shown. The conventional organic light emitting diode 10 comprises a capping 11, a cathode 12, an electron-injecting layer (EIL) 13, an electron-transporting layer (ETL) 14, a hole-blocking layer (HBL) 15, an emission layer (EML) 16, a hole-transporting layer (HTL) 17, a hole-injecting layer (HIL) 18 and an anode 19.

Referring to FIG. 2, a schematic illustration of light transportation of the conventional organic light emitting diode of FIG. 1 is shown. In the conventional organic light emitting diode 10, light goes through many different materials. This makes each of the three primary-color lights, namely, red light, green light and blue light, have a different luminous intensity distribution in different view angles due to the interference effect. For example, light emitted from the emission layer (EML) 16 will radiate upwardly or downwardly, wherein the light that radiates downwardly goes through the hole-transporting layer (HTL) 17 and hole-injecting layer (HIL) 18, is reflected by the anode 19, then interferes with the light that radiates upwardly. As a result, each of the three primary-color lights has a different luminous intensity distribution in different view angles, and the mixture of colors will cause the color shift effect on display.

Referring to FIG. 3, a cross-sectional view of a conventional organic light emitting diode display device is shown. The conventional display device 20 comprises a substrate 21, a display module 22 and a glass cap 23. The display module 22 is attached to the upper surface of the substrate 21 and is an organic light emitting diode adapted for emitting light. The light emitted from the display module 22 includes three primary-color lights, namely, red light, green light and blue light. The glass cap 23 is disposed above the display module 22 and sealed with the substrate 21 by sealant 24 for capping the display module 22 to form a package structure.

Referring to FIG. 4, luminous intensity distributions of the three primary-color lights emitted from a conventional organic light emitting diode display device 20 observed in different view angles are shown, wherein zero degree represents that the observation is at the vertical direction, the positive degree represents that the observation is at the right side of the vertical direction, and the negative degree represents that the observation is at the left side of the vertical direction. The disadvantage of the conventional organic light emitting diode display device 20 is that the three primary-color lights have different luminous intensity distribution in different view angles. Curve A in the figure is a luminous intensity distribution of red light; Curve B in the figure is a luminous intensity distribution of green light; Curve C in the figure is a luminous intensity distribution of blue light. As shown in the figure, the luminous intensity distributions of green light and blue light are like inverse U-letter and have the largest luminous intensity value at view angle of zero degree; the luminous intensity distribution of red light is a bimodal distribution and has the largest luminous intensity value at view angles of +40 degrees and −40 degrees. Therefore, the luminous intensity distribution of red light is very different from those of the other two primary-color lights, i.e., green light and blue light, which causes the color shift effect. For example, if the luminous intensity of each of the three primary-color lights is adjusted to be consistent with the other ones at view angle of zero degree, the resultant light observed would be white. However, if the above-mentioned resultant light is observed at other view angles, it is not a white light. Such a color shift effect is a problem in color adjustment.

Consequently, there is an existing need for a novel and improved display device to solve the above-mentioned problem.

### SUMMARY OF THE INVENTION

The primary objective of the invention is to provide a display device having a lenticular lens therein so as to improve the disunity of the luminous intensity distribution of the light emitted by the display device in different view angles, which facilitates color control.

The other objective of the invention is to provide a display device comprising a substrate, a display module, a lenticular lens and a cap. The display module is attached to the substrate and used for emitting light. The lenticular lens is disposed above the display module and used for changing the luminous intensity distribution of the light emitted by the display module. The cap is disposed above the lenticular lens and sealed with the substrate for capping the lenticular lens and the display module.

### BRIEF DESCRIPTION OF THE DRAWINGS

FIG. 1 is a cross-sectional view of a conventional organic light emitting diode;

FIG. 2 is a schematic illustration of light transportation of the conventional organic light emitting diode of FIG. 1;

FIG. 3 is a cross-sectional view of a conventional organic light emitting diode display device;

FIG. 4 are luminous intensity distributions of three primary-color lights emitted from a conventional organic light emitting diode display device observed in different view angles;

FIG. 5 is a cross-sectional view of an organic light emitting diode display device according to the first embodiment of the present invention;

FIG. 6 is a luminous intensity distribution of red light emitted from the organic light emitting diode display device according to the first embodiment of the present invention;

FIG. 7 is a cross-sectional view of an organic light emitting diode display device according to the second embodiment of the present invention is shown;

FIG. 8 is a luminous intensity distribution of red light emitted from the organic light emitting diode display device according to the second embodiment of the present invention is shown, wherein the glass cap does not touch the display module;

FIG. 9 is a luminous intensity distribution of red light emitted from the organic light emitting diode display device according to the second embodiment of the present invention is shown, wherein the glass cap touches the display module directly;

FIG. 10 is a cross-sectional view of an organic light emitting diode display device according to the third embodiment of the present invention; and

FIG. 11 is a cross-sectional view of an organic light emitting diode display device according to the fourth embodiment of the present invention.

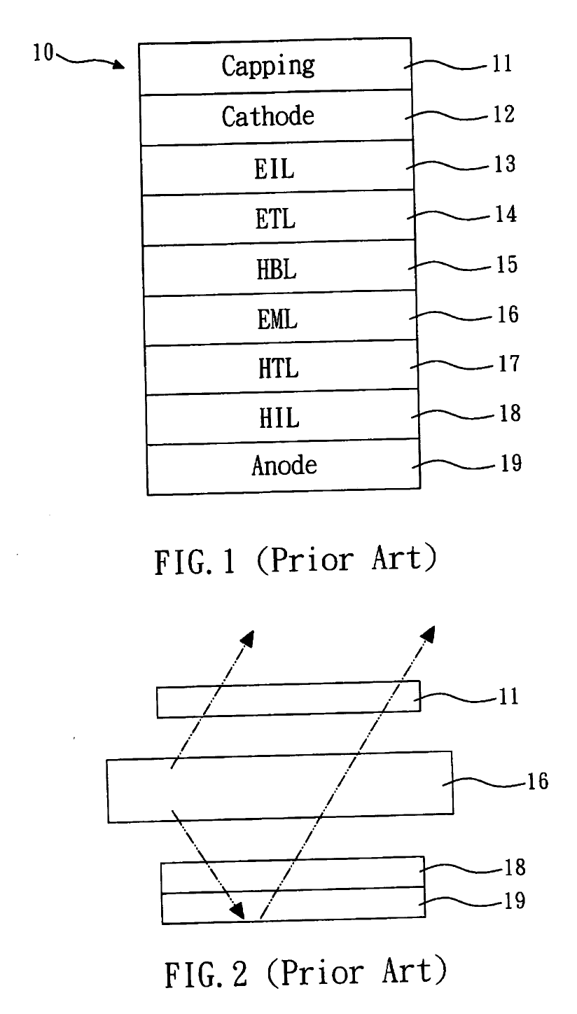

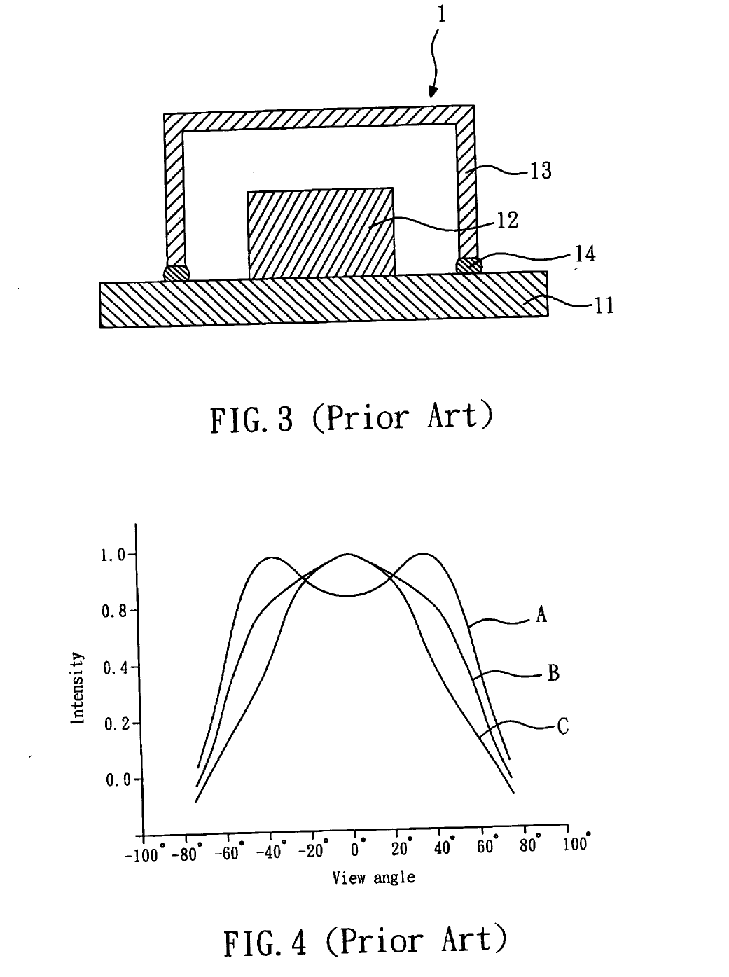

### DETAILED DESCRIPTION OF THE INVENTION

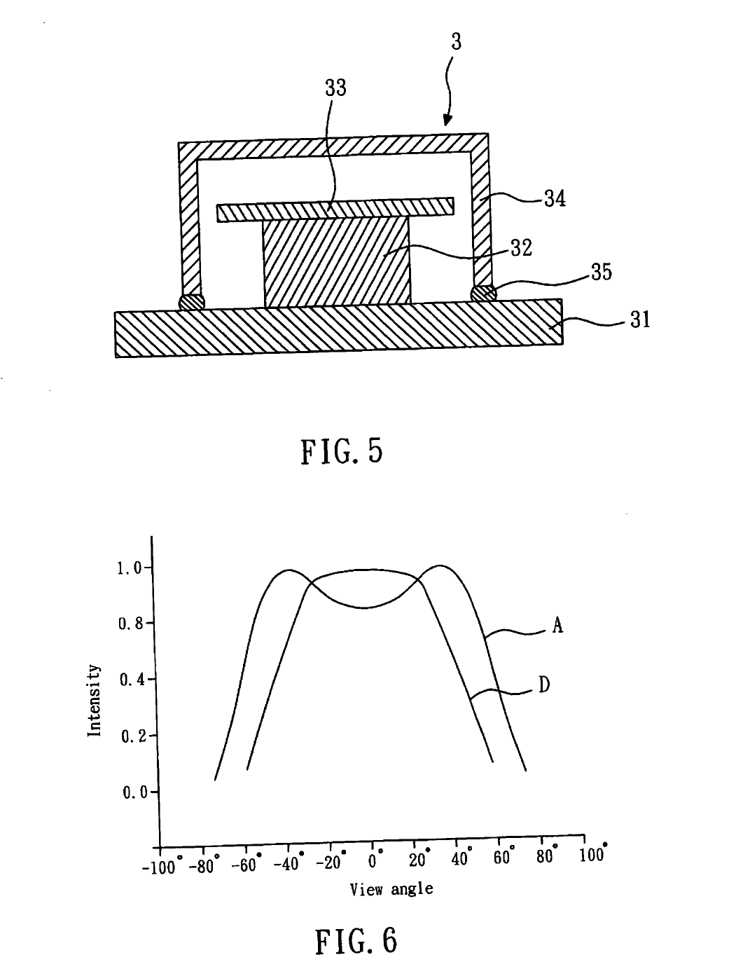

Referring to FIG. 5, a cross-sectional view of an organic light emitting diode display device according to the first embodiment of the present invention is shown. The display device 30 comprises a substrate 31, a display module (for example, a organic light emitting diode) 32, a lenticular lens 33 and a cap (for example, a glass cap) 34.

The display module 32 is attached to the upper surface of the substrate 31 and adapted for emitting light. The light emitted from the display module 32 includes three primary-color lights, namely red light, green light and blue light.

The lenticular lens 33 is a typical element, which is provided by Entire Tech. Co., Ltd, and its model number is PLS-99. The lenticular lens 33 is disposed above the display module 32 and has the function of diverging light, which is used for changing the luminous intensity distribution of the red light emitted by the display module 32. In the embodiment, the lenticular lens 33 is adhered to the upper surface of the display module 32 by utilizing UV curing adhesives or hot melt adhesives and disposed apart from the cap 34 by a predetermined distance. The thickness of the UV curing adhesives or hot melt adhesives is about 12.m.

In the embodiment, the cap is a glass cap 34 with legs that are sealed with the substrate 31 by sealant 35. The glass cap 34 is used for capping the display module 32 and lenticular lens 33 to form a package structure. Alternatively, the cap has a recess for accommodating the display module 32 or the lenticular lens 33. The recess is adjustable.

The display device 30 of this embodiment is made by the following steps: (a) providing a substrate 31; (b) attaching a display module 32 onto the substrate 31; (c) disposing a lenticular lens 33 above the display module 32 wherein the lenticular lens 33 is attached to the upper surface of the display module 32; (d) disposing a cap 34 above the lenticular lens 33; and (e) sealing the cap 34 with the substrate 31 for capping the lenticular lens 33 and the display module 32.

Referring to FIG. 6, a luminous intensity distribution of red light emitted from the organic light emitting diode display device according to the first embodiment of the present invention is shown, wherein the testing instrument used is TOPCON BM-7 luminance meter (the following embodiments are tested by this instrument). Curve A in the figure is a luminous intensity distribution of red light of a conventional organic light emitting diode display device, i.e., curve A of FIG. 4. Curve D in the figure is a luminous intensity distribution of red light that is like an inverse U-letter. As shown in the curve, the red light of the first embodiment has the largest luminous intensity value at view angles of +30 degrees and −30 degrees. The embodiment can be used when the luminous intensity distributions of green light and blue light are like an inverse U-letter.

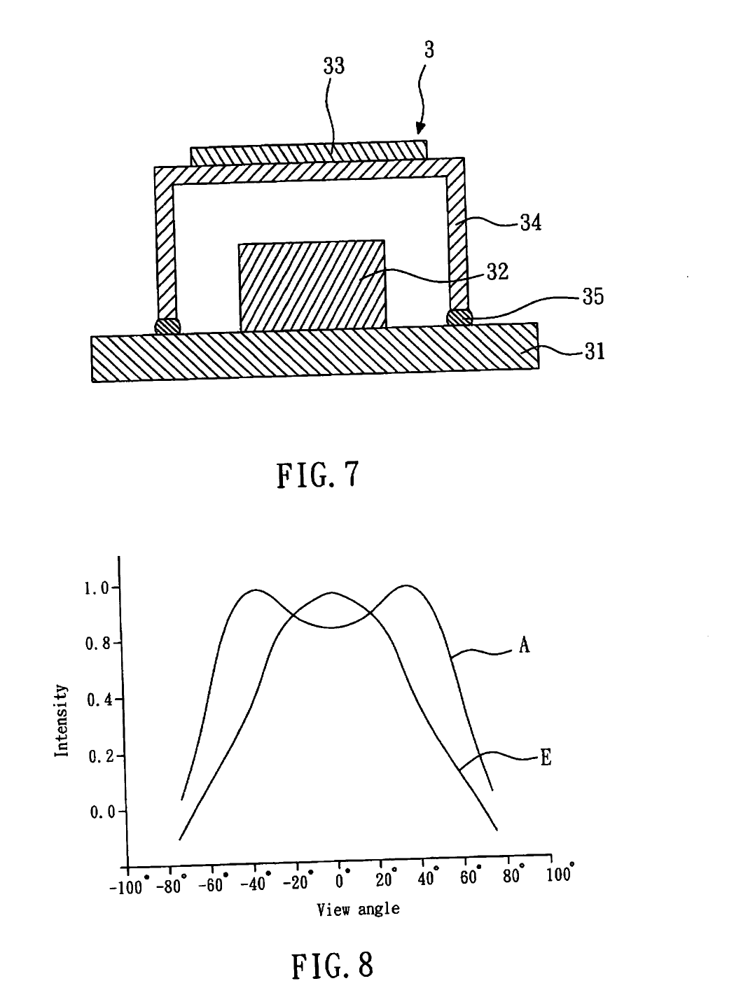

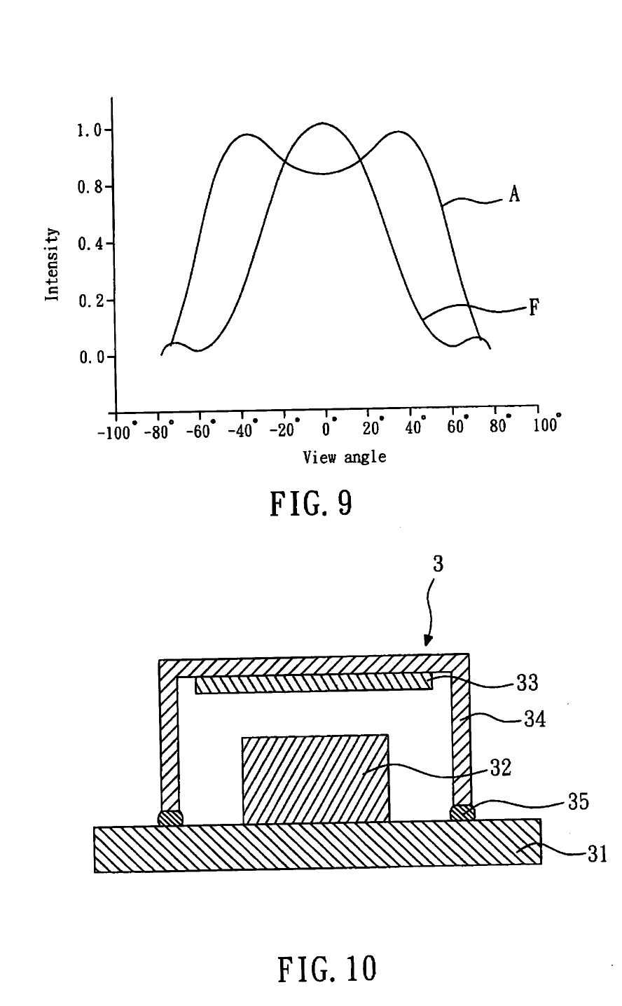

Referring to FIG. 7, a cross-sectional view of an organic light emitting diode display device according to the second embodiment of the present invention is shown. This embodiment is substantially similar to the first embodiment except the position of lenticular lens 33 is different. In this embodiment, the lenticular lens 33 is attached to the upper surface of the glass cap 34. The advantage of this embodiment is that the distance between the lenticular lens 33 and the display module 32 can be adjusted by changing the height of the glass cap 34 to obtain the desired luminous intensity distribution of red light according to the luminous intensity distributions of green light and blue light in the display device. The minimum value of the preferable range of the distance between the lenticular lens 33 and the display module 32 is the thickness of the glass cap 34, that is, the glass cap 34 touches the display module 32 directly. The luminous intensity distribution of red light in such condition is shown in curve F of FIG. 9. The maximum value of the preferable range of the distance between the lenticular lens 33 and the display module 32 is about 1.1 mm, and the luminous intensity distribution of red light in such condition is shown in curve E of FIG. 8.

The display device 30 of this embodiment is made by the following steps: (a) providing a substrate 31; (b) attaching a display module 32 onto the substrate 31; (c) providing a lenticular lens 33 and a cap 34, wherein the cap 34 has a upper surface thereof and a lower surface thereof; (d) attaching the lenticular lens 33 to the upper surface of the cap 34; and (e) sealing the cap 34 with the substrate 31 for capping the display module 32.

Referring to FIG. 8, a luminous intensity distribution of red light emitted from the organic light emitting diode display device according to the second embodiment of the present invention is shown, wherein the glass cap 34 does not touch the display module 32. Curve A in the figure is a luminous intensity distribution of red light of a conventional organic light emitting diode display device, i.e., curve A of FIG. 4. Curve E in the figure is a luminous intensity distribution of red light under this condition of the second embodiment. In comparison with curve A, curve E has the largest luminous intensity value at the view angle of zero degree and approaches curves B and C shown in FIG. 4. As a result, the luminous intensity distributions of three primary-color lights are fairly consistent with each other so as to facilitate color control.

Referring to FIG. 9, a luminous intensity distribution of red light emitted from the organic light emitting diode display device according to the second embodiment of the present invention is shown, wherein the glass cap 34 touches the display module 32 directly. Curve A in the figure is a luminous intensity distribution of red light of a conventional organic light emitting diode display device, i.e., curve A of FIG. 4. Curve E in the figure is a luminous intensity distribution of red light under this condition of second embodiment. In comparison with curve A, curve E has the largest luminous intensity value at the view angle of zero degree. Curve F is similar to curve E (FIG. 8) except that slope of curve F is larger than that of curve E.

Referring to FIG. 10, a cross-sectional view of an organic light emitting diode display device according to the third embodiment of the present invention is shown. This embodiment is substantially similar to the first embodiment except for the position of lenticular lens 33. In this embodiment, the lenticular lens 33 is attached to the lower surface inside the glass cap 34.

The display device 30 of this embodiment is made by the following steps: (a) providing a substrate 31; (b) attaching a display module 32 onto the substrate 31; (c) providing a lenticular lens 33 and a cap 34, wherein the cap 34 has a upper surface thereof and a lower surface thereof; (d) attaching the lenticular lens 33 to the lower surface of the cap 34; and (e) sealing the cap 34 with the substrate 31 for capping the display module 32.

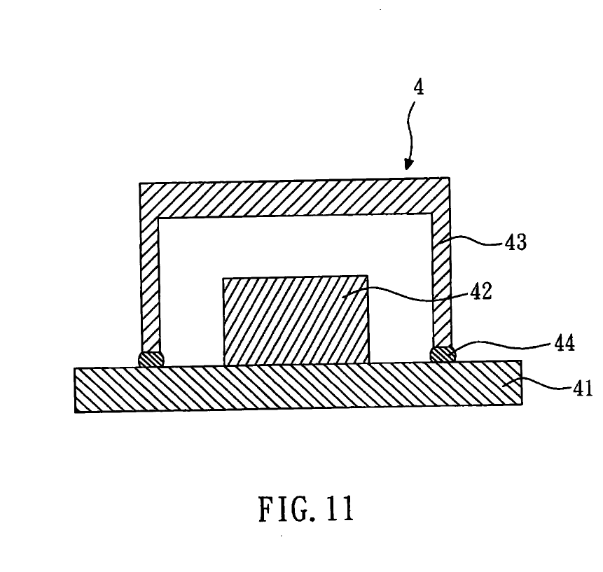

Referring to FIG. 11, a cross-sectional view of an organic light emitting diode display device 40 according to the fourth embodiment of the present invention is shown. This embodiment is substantially similar to the third embodiment except that the glass cap 34 and lenticular lens 33 in the third embodiment are replaced by a combined lenticular lens 43 in this fourth embodiment. As shown in the figure, the combined lenticular lens 43 itself has a cap-like shape with legs that are sealed with the substrate 41 by sealant 44 for capping the display module 42 to form a package structure. Therefore, the manufacturing and assembly cost caused by attaching the lenticular lens to the glass cap are reduced.

The display device 40 of this embodiment is made by the following steps: (a) providing a substrate 41; (b) attaching a display module 42 onto the substrate 41; (c) providing a lenticular lens 43, wherein the lenticular lens 43 is in a cap-like shape and is used for changing the luminous intensity distribution of the light emitted by the display module 42; (d) disposing the lenticular lens 43 above the display module 42; and (e) sealing the lenticular lens 43 with the substrate 41 for capping the display module 42.

While several embodiments of this invention have been illustrated and described, various modifications and improvements can be made by those skilled in the art. The embodiments of this invention are therefore described in an illustrative but not restrictive sense. It is intended that this invention may not be limited to the particular forms as illustrated, and that all modifications which maintain the spirit and scope of this invention are within the scope as defined in the appended claims.

1. A display device comprising:
a substrate;
a display module attached to the substrate and used for emitting light;
a lenticular lens disposed above the display module and used for changing the luminous intensity distribution of the light emitted by the display module; and
a cap disposed above the lenticular lens and sealed with the substrate for capping the lenticular lens and the display module.

2. A display device according to claim 1, wherein the light emitted by the display module comprises red light, blue light and green light, the lenticular lens is adapted for changing the luminous intensity distribution of the red light to approach the luminous intensity distribution of blue light and green light.

3. A display device according to claim 1, wherein the display module is an organic light emitting diode.

4. A display device according to claim 1, wherein the lenticular lens is attached to the cap and disposed apart from the display module by a predetermined distance.

5. A display device according to claim 1, wherein the lenticular lens is attached to the display module and disposed apart from the cap by a predetermined distance.

6. A display device according to claim 1, wherein the cap is a glass cap.

7. A display device comprising:
a substrate;
a display module attached to the substrate and used for emitting light;
a cap disposed above the display module and sealed with the substrate for capping the display module; and
a lenticular lens attached to the cap and used for changing the luminous intensity distribution of the light emitted by the display module.

8. A display device according to claim 7, wherein the light emitted by the display module comprises red light, and the lenticular lens is adapted for changing the luminous intensity distribution of the red light.

9. A display device according to claim 7, wherein the display module is an organic light emitting diode.

10. A display device according to claim 7, wherein the cap is a glass cap.

11. A display device comprising:
a substrate;
a display module attached to the substrate and used for emitting light; and
a lenticular lens disposed above the display module and used for changing the luminous intensity distribution of the light emitted by the display module, wherein the lenticular lens is in a cap-like shape and is adapt to seal with the substrate for capping the display module.

12. A display device according to claim 11, wherein the light emitted by the display module comprises red light, and the lenticular lens is adapted for changing the luminous intensity distribution of the red light.

13. A display device according to claim 11, wherein the display module is an organic light emitting diode.

14. A display device comprising:
a substrate;
a display module attached to the substrate and used for emitting light; and
a lenticular lens disposed above and apart from the display module by a predetermined distance which is adjusted for changing the luminous intensity distribution of the light emitted by the display module.

15. A method for changing the luminous intensity distribution of the light emitted by a display device, the display device having a display module, characterized in that disposing a lenticular lens above the display module.

16. A method for making a display device, comprising:
(a) providing a substrate;
(b) attaching a display module onto the substrate;
(c) disposing a lenticular lens above the display module;
(d) disposing a cap above the lenticular lens; and
(e) sealing the cap with the substrate for capping the lenticular lens and the display module.

17. A method according to claim 16, wherein the lenticular lens is attached to the display module in step (c).

18. A method for making a display device, comprising:
(a) providing a substrate;
(b) attaching a display module onto the substrate;
(c) providing a lenticular lens and a cap, wherein the cap has a upper surface thereof and a lower surface thereof;
(d) attaching the lenticular lens to the cap; and
(e) sealing the cap with the substrate for capping the display module.

19. A method according to claim 18, wherein the lenticular lens is attached to the upper surface of the cap in step (d).

20. A method according to claim 18, wherein the lenticular lens is attached to the lower surface of the cap in step (d).

21. A method for making a display device, comprising:
(a) providing a substrate;
(b) attaching a display module onto the substrate;
(c) providing a lenticular lens, wherein the lenticular lens is in a cap-like shape and is used for changing the luminous intensity distribution of the light emitted by the display module;
(d) disposing the lenticular lens above the display module; and
(e) sealing the lenticular lens with the substrate for capping the display module.
